(19) United States
(12) Patent Application Publication
(10) Pub. No.: US 2019/0057973 A1
(43) Pub. Date: Feb. 21, 2019

(54) SEMICONDUCTOR DEVICE

(71) Applicant: Toshiba Memory Corporation, Minato-ku (JP)

(72) Inventors: Takashi TERADA, Yokkaichi (JP); Ryuma YAMAMOTO, Yokkaichi (JP)

(73) Assignee: Toshiba Memory Corporation, Minato-ku (JP)

(21) Appl. No.: 15/955,169

(22) Filed: Apr. 17, 2018

(30) Foreign Application Priority Data
Aug. 21, 2017 (JP) 2017-158813

(51) Int. Cl. H01L 27/11573; H01L 27/1157; H01L 27/11582; H01L 23/00

(52) U.S. Cl. CPC H01L 27/11573; H01L 23/564; H01L 27/11582; H01L 27/1157

(57) ABSTRACT

A semiconductor device includes a semiconductor substrate, a stacked body, a transistor, first and second silicon oxides, and a first silicon nitride film. The semiconductor substrate includes a cell region. The stacked body is provided in the cell region and included in a memory cell array. The transistor is disposed on the semiconductor substrate between the stacked body and an edge portion of the semiconductor substrate. The first silicon oxide film surrounds the stacked body and is disposed between the stacked body and the transistor. The second silicon oxide film surrounds the first silicon oxide film, is separated from the first silicon oxide film, and is disposed between the edge portion and the first silicon oxide film. The first silicon nitride film includes a portion provided on the substrate in a first region. The portion surrounds the stacked body.

### CROSS-REFERENCE TO RELATED APPLICATIONS

This application is based upon and claims the benefit of priority from Japanese Patent Application No. 2017-158813, filed on Aug. 21, 2017; the entire contents of which are incorporated herein by reference.

### FIELD

Embodiments described herein relate generally to a semiconductor device.

### BACKGROUND

Downscaling is advancing for a semiconductor element of a semiconductor device. Due to the advancement of the downscaling of the semiconductor element, the leakage current and the fluctuation of the element characteristics of the semiconductor element have reached a level that is extremely slight but cannot be ignored. Or, it has become difficult to suppress the leakage current and the element characteristics to be within the design values. For example, nonvolatile memory is known in which insulating layers and conductive layers are stacked alternately in a stacked body, and memory cells are stacked in a three-dimensional structure in the height direction of the stacked body. The effects of the extremely slight leakage current and fluctuation of the element characteristics recited above are particularly pronounced in a peripheral circuit of the nonvolatile memory including the memory cells having the three-dimensional structure. A semiconductor device is desirable in which it is possible to suppress the leakage current and/or the fluctuation of the element characteristics of the semiconductor element, e.g., the degradation of the hump characteristic of a transistor.

### BRIEF DESCRIPTION OF THE DRAWINGS

FIG. 1A is a schematic plan view illustrating a semiconductor device according to an embodiment, and FIG. 1B is a schematic plan view illustrating the wafer state of the semiconductor device according to the embodiment;

FIG. 2 is a schematic cross-sectional view along line II-II in FIG. 1A;

FIG. 3A is a schematic plan view illustrating a planar pattern of first to fourth element separation regions, FIG. 3B is a schematic plan view illustrating a planar pattern of first to third silicon oxide films, and FIG. 3C is a schematic plan view illustrating a planar pattern of the first silicon nitride film;

FIG. 4A is a schematic cross-sectional view illustrating a semiconductor device according to a reference example, FIG. 4B is a schematic cross-sectional view illustrating the semiconductor device according to the embodiment;

FIG. 5A to FIG. 5D are schematic cross-sectional views in order of the processes, illustrating a method for manufacturing the semiconductor device according to the embodiment;

FIG. 6 is a schematic cross-sectional view illustrating a semiconductor device according to a first variation of the embodiment;

FIG. 7 is a schematic cross-sectional view illustrating a semiconductor device according to a second variation of the embodiment;

FIG. 8A is a schematic cross-sectional view illustrating a state before dicing the semiconductor device according to the embodiment, and FIG. 8B is a schematic cross-sectional view illustrating a state during the manufacturing of the semiconductor device according to the embodiment; and

FIG. 9 is a schematic cross-sectional view illustrating memory cells having a three-dimensional structure.

### DETAILED DESCRIPTION

According to one embodiment, a semiconductor device includes a semiconductor substrate of a first conductivity type, a stacked body, a transistor, a first silicon oxide film, a second silicon oxide, and a first silicon nitride film. The semiconductor substrate includes a cell region. The cell region spreads in a second direction and in a third direction. The second direction crosses a first direction, and the third direction crosses the first direction and the second direction. The stacked body is provided in the cell region and included in a memory cell array. The stacked body includes a conductive layer and an insulating layer stacked alternately along the first direction. The transistor is disposed on the semiconductor substrate between the stacked body and an edge portion of the semiconductor substrate. The transistor is included in a peripheral circuit of the memory cell array. The first silicon oxide film surrounds the stacked body in the second and third directions on the semiconductor substrate and is disposed between the stacked body and the transistor. The second silicon oxide film surrounds the first silicon oxide film and is separated from the first silicon oxide film in the second and third directions on the semiconductor substrate. The second silicon oxide film is disposed between the edge portion and the first silicon oxide film. The first silicon nitride film includes a portion provided on the substrate in a first region. The first region is positioned between the stacked body and the transistor and between the first silicon oxide film and the second silicon oxide film. The portion surrounds the stacked body in the second and third directions on the semiconductor substrate.

Various embodiments will be described hereinafter with reference to the accompanying drawings.

The drawings are schematic and conceptual; and the relationships between the thickness and width of portions, the proportions of sizes among portions, etc., are not necessarily the same as the actual values thereof. Further, the dimensions and proportions may be illustrated differently among drawings, even for identical portions.

In the specification and drawings, components similar to those described or illustrated in a drawing thereinabove are marked with like reference numerals, and a detailed description is omitted as appropriate.

### Embodiment

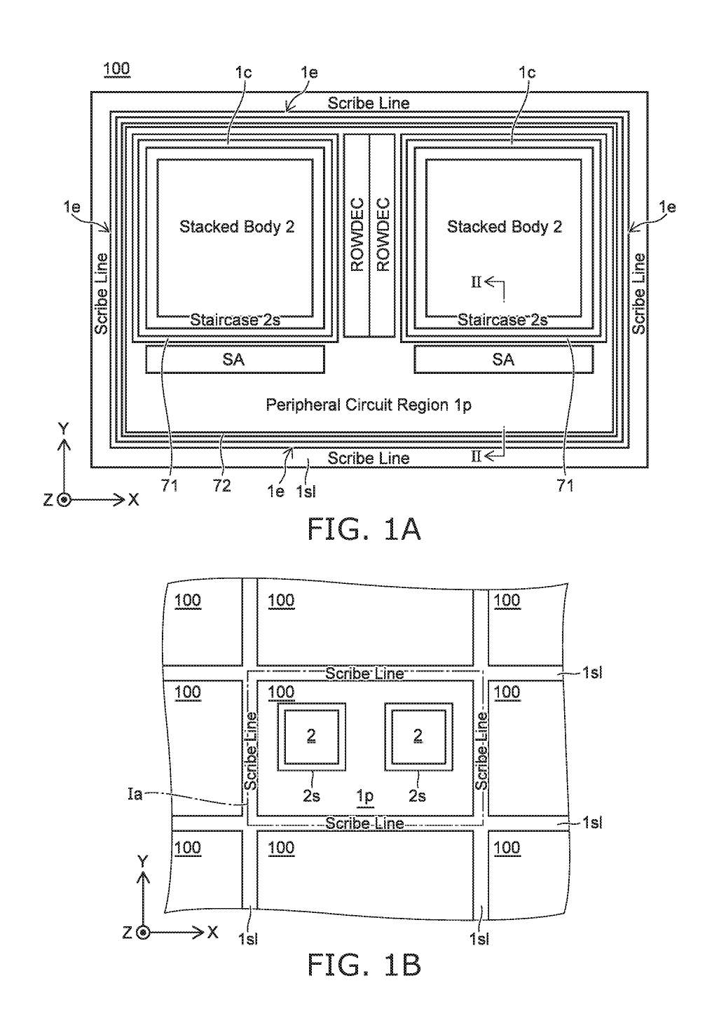

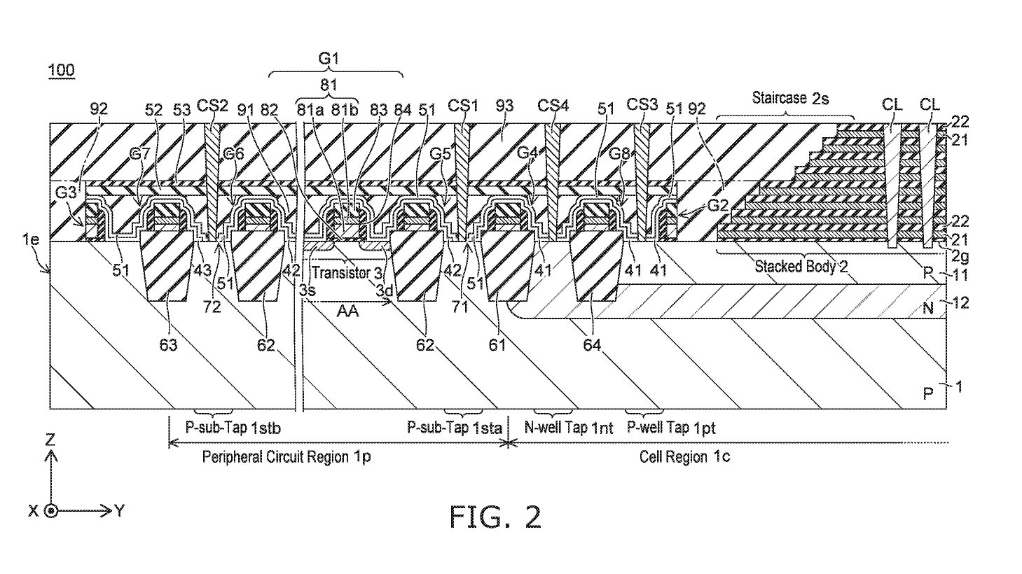

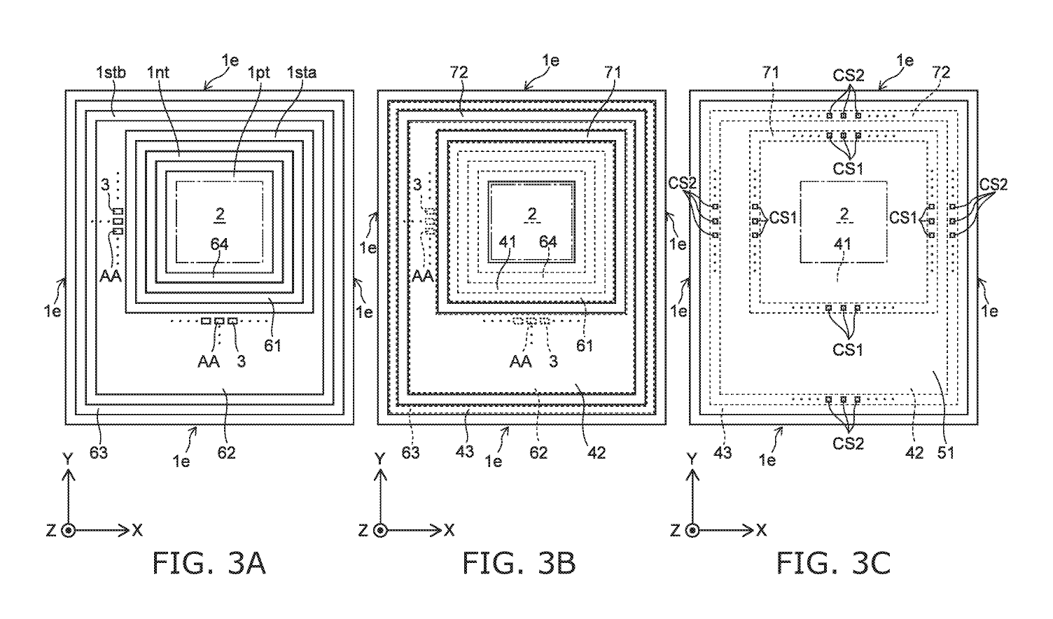

FIG. 1A is a schematic plan view illustrating a semiconductor device according to an embodiment. FIG. 1B is a schematic plan view illustrating the wafer state of the semiconductor device according to the embodiment. FIG. 1A corresponds to an enlarged view of single dot-dash line box Ia in FIG. 1B. FIG. 2 is a schematic cross-sectional view along line II-II in FIG. 1A. FIG. 3A is a schematic plan view illustrating a planar pattern of first to fourth element separation regions. FIG. 3B is a schematic plan view illustrating a planar pattern of first to third silicon oxide films. FIG. 3C is a schematic plan view illustrating a planar pattern of the first silicon nitride film. The drawings are simplified in FIG. 3A to FIG. 3C by showing one cell region. A first direction, a second direction, and a third direction are shown in FIG. 1A to FIG. 3C. In the specification, the first direction is taken as a Z-axis direction. One direction that crosses, e.g., is orthogonal to, the Z-axis direction is taken as the second direction. The second direction is an X-axis direction. One direction is taken as the third direction that crosses, e.g., is orthogonal to, the Z- and X-axis directions. The third direction is a Y-axis direction.

As shown in FIG. 1A to FIG. 2, the semiconductor device 100 according to the embodiment includes a semiconductor substrate 1 of a first conductivity type, a stacked body (Stacked Body) 2, a transistor (Transistor) 3, first to third silicon oxide films 41 to 43, and a first silicon nitride film 51.

The semiconductor substrate 1 includes a cell region (Cell Region) 1c, a peripheral circuit region (Peripheral Circuit Region) 1p, and an edge portion 1e. The cell region 1c spreads in the X- and Y-axis directions. The peripheral circuit region 1p is adjacent to the cell region 1c in the X- and Y-axis directions. Although the edge portion 1e does not exist in the wafer state, the edge portion 1e appears as the end surface of the semiconductor chip when the wafer is diced along a scribe line (Scribe Line) 1sl. The peripheral circuit region 1p is positioned between the cell region 1c and the edge portion 1e.

A first semiconductor region 11 of the first conductivity type and a second semiconductor region 12 of a second conductivity type are provided inside the semiconductor substrate 1. The first and second semiconductor regions 11 and 12 each are, for example, well regions. The first semiconductor region 11 is positioned inside the cell region 1c and is electrically isolated from the semiconductor substrate 1 by the second semiconductor region 12. In the specification, the first conductivity type is a P-type; and the second conductivity type is an N-type. The semiconductor includes, for example, silicon. In the drawing, the well regions other than the first and second semiconductor regions 11 and 12 are not illustrated.

The stacked body 2 is disposed inside the cell region 1c and is provided on the semiconductor substrate 1. In the embodiment, the stacked body 2 is provided on the first semiconductor region 11. For example, an insulating film 2g is provided between the stacked body 2 and the first semiconductor region 11. The stacked body 2 includes multiple conductive layers 21 and multiple insulating layers 22 stacked alternately along the Z-axis direction and is included in, for example, a memory cell array of nonvolatile memory. For example, a staircase portion (Staircase) 2s is provided at the periphery of the stacked body 2. In the staircase portion 2s, the conductive layers 21 and the insulating layers 22 are drawn out one layer at a time outside the stacked body 2. The staircase portion 2s is a contact region where electrical interconnects are connected respectively to the conductive layers 21. FIG. 2 shows a YZ cross section. The electrical interconnects that are connected to the conductive layers 21 are not illustrated in the case where the Y-axis direction is, for example, the direction in which the bit lines (not illustrated) extend. Multiple columnar portions CL are provided inside the stacked body 2. The columnar portions CL each extend in the Z-axis direction through the stacked body 2 and include multiple memory cells. An example of the memory cell is described below. Although an example of two stacked bodies 2 is shown in FIGS. 1A and 1B, there may be one, three, or more stacked bodies 2.

First to fourth element separation regions 61 to 64 are provided inside the semiconductor substrate 1. The first to fourth element separation regions 61 to 64 each include silicon oxide. The first element separation region 61 is disposed between the edge portion 1e and the stacked body 2; and the first element separation region 61 surrounds the stacked body 2 and is separated from the stacked body 2 in the X- and Y-axis directions (FIG. 3A). For example, the first element separation region 61 is provided in the cell region 1c and in the peripheral circuit region 1p. The second element separation region 62 is disposed between the edge portion 1e and the first element separation region 61; and the second element separation region 62 surrounds the first element separation region 61 and is separated from the first element separation region 61 in the X- and Y-axis directions (FIG. 3A). For example, the second element separation region 62 is provided in the peripheral circuit region 1p. The third element separation region 63 is disposed between the edge portion 1e and the second element separation region 62; and the third element separation region 63 surrounds the second element separation region 62 and is separated from the second element separation region 62 in the X- and Y-axis directions (FIG. 3A). The fourth element separation region 64 is disposed between the stacked body 2 and the first element separation region 61; and the fourth element separation region 64 surrounds the stacked body 2 and is separated from the stacked body 2 and from the first element separation region 61 in the X- and Y-axis directions (FIG. 3A). For example, the fourth element separation region 64 is provided in the cell region 1c of the semiconductor substrate 1. Also, the fourth element separation region 64 separates the first semiconductor region 11 and the second semiconductor region 12 in the X- and Y-axis directions.

The semiconductor substrate 1 includes a first tap region (P-sub Tap) 1sta, a second tap region (P-well Tap) 1pt, a third tap region (N-well Tap) 1nt, and a fourth tap region (P-sub Tap) 1stb. The first and fourth tap regions 1sta and 1stb each are regions where electrical interconnects that supply bias voltages to the semiconductor substrate 1 are connected. The first tap region 1sta is positioned between the first element separation region 61 and the second element separation region 62 and surrounds the stacked body 2 in the X- and Y-axis directions. The fourth tap region 1stb is positioned between the second element separation region 62 and the third element separation region 63 and surrounds the second element separation region 62 in the X- and Y-axis directions. The second tap region 1pt is a region where an electrical interconnect that supplies a bias voltage to the first semiconductor region 11 is connected. The second tap region 1pt is positioned between the stacked body 2 and the fourth element separation region 64. The third tap region 1nt is a region where an electrical interconnect that supplies a bias voltage to the second semiconductor region 12 is connected. The third tap region 1nt is positioned between the fourth element separation region 64 and the first element separation region 61.

The transistor 3 is disposed between the edge portion 1e and the stacked body 2 and is provided inside the peripheral circuit region 1p. Although only one transistor 3 is shown in the drawing, actually there are multiple transistors 3. For example, the transistors 3 are included in a peripheral circuit of the memory cell array such as a row decoder (ROWDEC), a sense amplifier (SA), etc. For example, the second element separation region 62 is formed between the first and fourth tap regions 1sta and 1stb in a pattern that multiply defines regions where the surface of the semiconductor substrate 1 is exposed. These defined regions each are active regions (AA). A source region 3s and a drain region 3d of the transistor 3 are provided in an active region.

The first silicon oxide film 41 is disposed between the stacked body 2 and the transistor 3. The first silicon oxide film 41 surrounds the stacked body 2 in the X- and Y-axis directions on the semiconductor substrate 1 (FIG. 3B). For example, the first silicon oxide film 41 is separated from the stacked body 2. For example, the first silicon oxide film 41 is provided on the cell region 1c and on the peripheral circuit region 1p of the semiconductor substrate 1. In the embodiment, the first silicon oxide film 41 covers the first and fourth element separation regions 61 and 64.

A second silicon oxide film 42 is disposed between the edge portion 1e and the first silicon oxide film 41. The second silicon oxide film 42 surrounds the first silicon oxide film 41 and is separated from the first silicon oxide film 41 in the X- and Y-axis directions on the semiconductor substrate 1 (FIG. 3B). For example, the second silicon oxide film 42 is provided on the peripheral circuit region 1p of the semiconductor substrate 1. In the embodiment, the second silicon oxide film 42 covers the second element separation region 62.

The third silicon oxide film 43 is disposed between the edge portion 1e and the second silicon oxide film 42. The third silicon oxide film 43 surrounds the second silicon oxide film 42 and is separated from the second silicon oxide film 42 in the X- and Y-axis directions on the semiconductor substrate 1 (FIG. 3B). For example, the third silicon oxide film 43 is provided on the peripheral circuit region 1p and on the region between the peripheral circuit region 1p and the edge portion 1e of the semiconductor substrate 1. In the embodiment, the third silicon oxide film 43 covers the third element separation region 63.

The first silicon nitride film 51 surrounds the stacked body 2 in the X- and Y-axis directions and is disposed at least between the transistor 3 and the stacked body 2. The first silicon nitride film 51 includes a portion provided on a first region 71. The first region 71 is positioned between the first silicon oxide film 41 and the second silicon oxide film 42 and is a portion where the surface of the semiconductor substrate 1 is exposed. For example, the first region 71 is positioned in the first tap region 1sta and surrounds the stacked body 2 in the X- and Y-axis directions (FIG. 1A and FIG. 3B). The first silicon nitride film 51 directly contacts the P-type silicon of the semiconductor substrate 1 surface in the first region 71. The first region 71 includes a Si/SiNₓ junction where silicon and silicon nitride are directly bonded. For example, such a Si/SiNₓ junction does not include silicon oxide. For example, the Si/SiNₓ junction does not transmit hydrogen easily. The first region 71 that includes the Si/SiNₓ junction functions as a hydrogen-blocking region. The hydrogen-blocking region that is provided in the first region 71 blocks the diffusion of hydrogen from the cell region 1c toward the peripheral circuit region 1p.

The first silicon nitride film 51 of the embodiment further includes a portion provided on a second region 72. The second region 72 is positioned between the second silicon oxide film 42 and the third silicon oxide film 43 and, similarly to the first region 71, is a portion where the surface of the semiconductor substrate 1 is exposed. For example, the second region 72 is positioned in the fourth tap region 1stb and surrounds the transistor 3 in the X- and Y-axis directions (FIG. 1A and FIG. 3B). The first silicon nitride film 51 directly contacts the P-type silicon of the semiconductor substrate 1 surface in the second region 72. The second region 72 also includes a Si/SiNₓ junction similar to that of the first region 71 and functions as a hydrogen-blocking region. The hydrogen-blocking region that is provided in the second region 72 blocks the diffusion of hydrogen from the scribe line 1sl toward the peripheral circuit region 1p.

In the embodiment, for example, the first silicon nitride film 51 is provided on the first region 71, the first to third silicon oxide films 41 to 43, and the second region 72 (FIG. 3C).

The transistor 3 includes a first gate structure body G1 provided in the peripheral circuit region 1p on the semiconductor substrate 1. The first gate structure body G1 includes a gate electrode 81, a gate insulating film 82, a capping film 83, and a sidewall spacer film 84 (FIG. 2). The gate electrode 81 includes a conductive silicon film 81a, and a metal film 81b provided on the upper surface of the conductive silicon film 81a. For example, the metal film 81b has a stacked structure of tungsten (W) and tungsten nitride (WN) (not illustrated). The gate insulating film 82 is provided between the gate electrode 81 and the semiconductor substrate 1 and includes silicon oxide. The capping film 83 is provided on the upper surface of the gate electrode 81 and includes, for example, silicon nitride. The sidewall spacer film 84 is provided on the side walls of the gate electrode 81 and the capping film 83 and includes, for example, silicon oxide. The first gate structure body G1 shown in FIG. 2 is an illustration and is not limited to the structure shown in FIG. 2.

The suppression of the degradation of the reliability of the transistor 3 is an example of one role of the first to third silicon oxide films 41 to 43. For example, a transistor that controls a high voltage (e.g., 10 to 20 V) used when programming data and/or when erasing data is included in the peripheral circuit region 1p of the nonvolatile memory. In the case where the first silicon nitride film 51 is provided directly on the semiconductor substrate 1 in the peripheral circuit region 1p, the first silicon nitride film 51 provides trap sites of charge and undesirably causes the threshold voltage of the transistor to increase. For example, such an increase of the threshold voltage can be suppressed by interposing, for example, the second silicon oxide film 42 between the first silicon nitride film 51 and the semiconductor substrate 1 where the source region 3s and the drain region 3d are provided. The first to third silicon oxide films 41 to 43 are provided in the embodiment from such a perspective. For example, the action of the first silicon nitride film 51 as trap sites can be suppressed by setting the thicknesses in the Z-axis direction of the first to third silicon oxide films 41 to 43 to be 10 nm or more.

Also, in the case where the first silicon nitride film 51 directly contacts the semiconductor substrate 1, there is a possibility that crystal defects may be induced in the semiconductor substrate 1 by stress.

The semiconductor device 100 of the embodiment further includes second to eighth gate structure bodies G2 to G8. The second to eighth gate structure bodies G2 to G8 each are dummy gate structure bodies. Each of these dummy gate structure bodies has a structure similar to that of the first gate structure body G1. The second gate structure body G2 is disposed between the first gate structure body G1 and the stacked body 2 and is provided inside the cell region 1c on the semiconductor substrate 1. For example, the second gate structure body G2 is provided on the first semiconductor region 11. A third gate structure body G3 is disposed between the first gate structure body G1 and the edge portion 1e and is provided in a region between the edge portion 1e and the third element separation region 63 on the semiconductor substrate 1. Fourth to eighth gate structure bodies G4 to G8 are provided respectively on the first to fourth element separation regions 61 to 64 (except that the two fifth and sixth gate structure bodies G5 and G6 are provided on the second element separation region 62).

The first silicon oxide film 41 covers the second, fourth, and eighth gate structure bodies G2, G4, and G8. The second silicon oxide film 42 covers the first, fifth, and sixth gate structure bodies G1, G5, and G6. The third silicon oxide film 43 covers the third and seventh gate structure bodies G3 and G7. The first silicon nitride film 51 covers, with one of the first to third silicon oxide films 41 to 43 interposed, the first to eighth gate structure bodies G1 to G8. A first inter-layer insulating film 91 is provided in each region between the first to eighth gate structure bodies G1 to G8. The first inter-layer insulating film 91 includes, for example, silicon oxide.

The semiconductor device 100 of the embodiment further includes a second silicon nitride film 52 and a silicon oxide film 53. The silicon oxide film 53 is a film used as a stopper when patterning the staircase portion 2s. The second silicon nitride film 52 is provided to be continuous on the first to eighth gate structure bodies G1 to G8 and the first inter-layer insulating film 91. In the embodiment, the first silicon nitride film 51 and one of the first to third silicon oxide films 41 to 43 are interposed between the second silicon nitride film 52 and each of the first to eighth gate structure bodies G1 to G8. For example, the second silicon nitride film 52 is provided from the second gate structure body G2 to the third gate structure body G3 and covers over at least the peripheral circuit region 1p. The first silicon nitride film 51 is positioned between the semiconductor substrate 1 and the second silicon nitride film 52.

The second silicon nitride film 52 is a film used as a stopper when forming contact holes to the semiconductor substrate 1. Similarly to the first silicon nitride film 51, the second silicon nitride film 52 can block the diffusion of hydrogen into the peripheral circuit region 1p. In particular, the second silicon nitride film 52 can block the hydrogen diffusing from above the peripheral circuit region 1p.

The first silicon nitride film 51 further covers over at least the peripheral circuit region 1p while covering the first to eighth gate structure bodies G1 to G8. In particular, the first silicon nitride film 51 covers, under the second silicon nitride film 52, the side surfaces of the second and third gate structure bodies G2 and G3 at the two ends facing the peripheral circuit region 1p (the side surfaces on the first gate structure body G1 side). Such a first silicon nitride film 51 blocks the hydrogen diffusing into the peripheral circuit region 1p from the side surfaces of the second and third gate structure bodies G2 and G3 facing the stacked body 2 and the scribe line 1sl.

A second inter-layer insulating film 92 is provided at the peripheries of the side walls of the second and third gate structure bodies G2 and G3 and the side walls of the second silicon nitride film 52 and the silicon oxide film 53. For example, the second inter-layer insulating film 92 is filled between the second gate structure body G2 and the stacked body 2. The second inter-layer insulating film 92 includes, for example, silicon oxide.

A third inter-layer insulating film 93 is provided on the silicon oxide film 53 and on the second inter-layer insulating film 92. The third inter-layer insulating film 93 includes, for example, silicon oxide.

The semiconductor device 100 of the embodiment includes first to fourth conductors CS1 to CS4. For example, the first conductor CS1 pierces the third inter-layer insulating film 93, the silicon oxide film 53, the second silicon nitride film 52, the first inter-layer insulating film 91, and the first silicon nitride film 51 and is electrically connected to the first region 71. For example, the second conductor CS2 pierces the third inter-layer insulating film 93, the silicon oxide film 53, the second silicon nitride film 52, the first inter-layer insulating film 91, and the first silicon nitride film 51 and is electrically connected to the second region 72. The first and second conductors CS1 and CS2 each are electrical interconnects that supply bias voltages to the semiconductor substrate 1. The third conductor CS3 pierces the third inter-layer insulating film 93, the silicon oxide film 53, the second silicon nitride film 52, the first inter-layer insulating film 91, the first silicon nitride film 51, and the first silicon oxide film 41 and is electrically connected to the first semiconductor region 11. The fourth conductor CS4 pierces the third inter-layer insulating film 93, the silicon oxide film 53, the second silicon nitride film 52, the first inter-layer insulating film 91, the first silicon nitride film 51, and the first silicon oxide film 41 and is electrically connected to the second semiconductor region 12. The third conductor CS3 is an electrical interconnect that supplies a bias voltage to the first semiconductor region 11; and the fourth conductor CS4 is an electrical interconnect that supplies a bias voltage to the second semiconductor region 12. Electrical interconnects other than the first to fourth conductors CS1 to CS4 also exist, but are not illustrated in the embodiment.

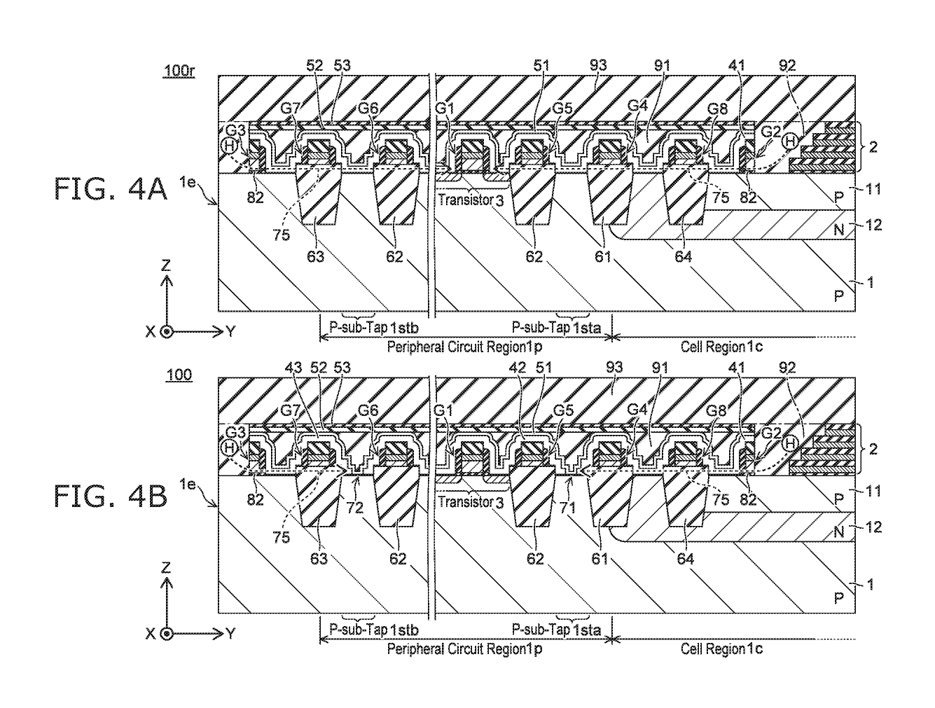

FIG. 4A is a schematic cross-sectional view illustrating a semiconductor device according to a reference example. FIG. 4B is a schematic cross-sectional view illustrating the semiconductor device according to the embodiment. FIGS. 4A and 4B show the first to third oxide films 41 to 43 with emphasis.

As shown in FIG. 4A, the semiconductor device 100r according to the reference example is an example that does not include the first and second regions 71 and 72. In the case where the first and second regions 71 and 72 are not included, for example, the first silicon oxide film 41 is provided from the cell region 1c to the peripheral circuit region 1p. A stacked structure of the first silicon oxide film 41 and the first silicon nitride film 51 is formed in the first and fourth tap regions 1sta and 1stb. In such a case, a path via the gate insulating film 82, the first silicon oxide film 41, and the first to fourth element separation regions 61 to 64 becomes a penetration path 75 of hydrogen (H).

The gate insulating film 82, the first silicon oxide film 41, and the first to fourth element separation regions 61 to 64 each include silicon oxide. Hydrogen diffuses through silicon oxide. Therefore, for example, there is a possibility that hydrogen, hydrides such as ammonia, etc., used to form the stacked body 2 may penetrate the peripheral circuit region 1p when forming the stacked body 2. For example, there are cases where the conductive layers 21 that are included in the stacked body 2 are formed by replacing sacrificial films (not illustrated). The sacrificial films include silicon nitride; and, for example, ammonia is used as a nitriding agent when forming the sacrificial films. Processes in which ammonia is used increase as the number of stacks of the conductive layers 21 of the stacked body 2 is increased.

Further, a characteristic improvement anneal of the memory cells is performed after forming the stacked body 2. Deuterium is used in the characteristic improvement anneal. There is a possibility that the deuterium may penetrate into the peripheral circuit region 1p during the characteristic improvement anneal.

The hydrogen and/or the deuterium that penetrates into the peripheral circuit region 1p undesirably reaches the transistor 3, the second element separation region 62, etc.

Currently, downscaling of the transistor 3 is advancing. Also, the number of times hydrogen and hydrides are used in the manufacturing processes is increasing. Further, the hydrogen that comes into contact with the semiconductor device is becoming excessive. Therefore, for example, the following circumstances (1) to (4) caused by the hydrogen in the manufacturing processes have reached a level that cannot be ignored. Or, it has become difficult to suppress the characteristic values relating to the circumstances (1) to (4), etc., to be within the design values.

(1) Degradation of the hump characteristic of the transistor

(2) Increase of the field leakage current

(3) Abnormal reaction of the conductive silicon film and the metal film inside the gate structure body

(4) Increase of the source-drain leakage current and the junction leakage current

Boron deactivation due to hydrogen is one cause of the circumstances (1) and (2). The circumstance (3) is barrier breakdown. For example, in the case where the metal film 81b has a stacked structure of W/WN, barrier breakdown occurs easily if there is a long manufacturing process using hydrogen and heat. The circumstance (4) is caused by crystal defects. The crystal defects worsen particularly easily in the characteristic improvement anneal.

Compared to the reference example as shown in FIG. 4B, in the semiconductor device 100 according to the embodiment, the first and second regions 71 and 72 are provided respectively in the first and fourth tap regions 1sta and 1stb; and the stacked structure of the semiconductor substrate 1 and the first silicon nitride film 51 is formed in each of the first and second regions 71 and 72. Compared to silicon oxide, silicon nitride does not transmit hydrogen easily. Therefore, the penetration path 75 of hydrogen is broken at the first and second regions 71 and 72. As a result, the penetration of the hydrogen and/or the deuterium into the peripheral circuit region 1p and the hydrogen and/or the deuterium that reaches the transistor 3 and/or the second element separation region 62 are suppressed.

Thus, according to the semiconductor device 100 according to the embodiment, compared to the semiconductor device 100r according to the reference example, it is possible to improve the circumstances (1) to (4), etc., recited above.

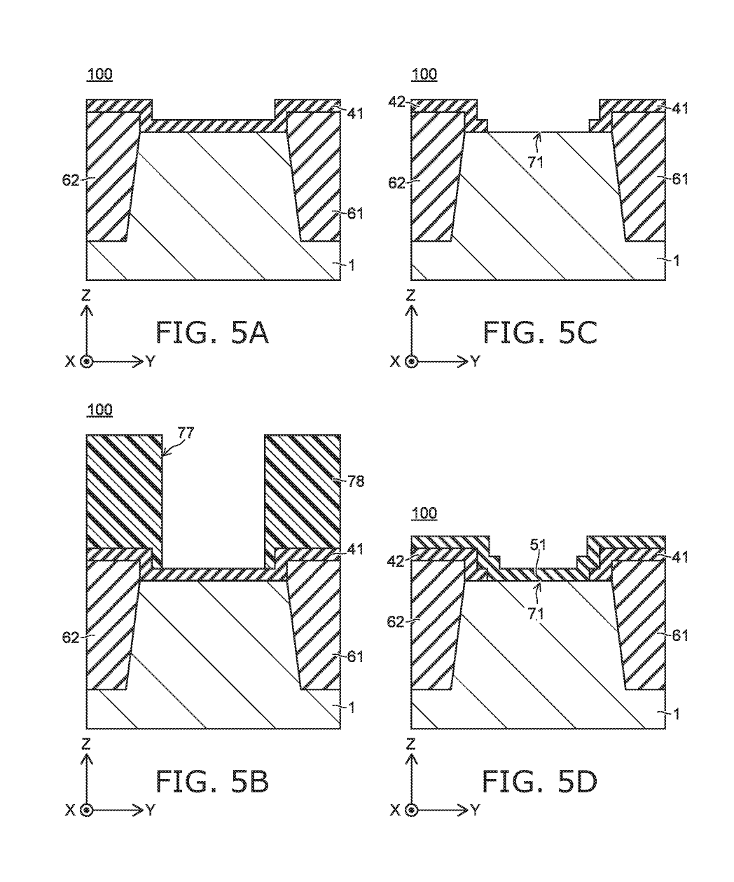

FIG. 5A to FIG. 5D are schematic cross-sectional views in order of the processes, illustrating a method for manufacturing the semiconductor device 100 according to the embodiment.

First, as shown in FIG. 5A, the first silicon oxide film 41 is formed using, for example, CVD (Chemical Vapor Deposition) on the semiconductor substrate 1 and the first to fourth element separation regions 61 to 64 (only the first and second element separation regions 61 and 62 are illustrated).

Then, as shown in FIG. 5B, a photoresist film 78 is formed by coating a photoresist onto the first silicon oxide film 41. Then, windows 77 that correspond to the first and second regions 71 and 72 are formed in the photoresist film 78 (only the window 77 corresponding to the first region 71 is illustrated).

Continuing as shown in FIG. 5C, the first silicon oxide film 41 is etched using the photoresist film 78 as a mask of the etching; and the surface of the semiconductor substrate 1 is exposed. Thereby, the first silicon oxide film 41 is subdivided into the first to third silicon oxide films 41 to 43. Thus, the first region 71 is formed between the first silicon oxide film 41 and the second silicon oxide film 42; and the second region 72 is formed between the second silicon oxide film 42 and the third silicon oxide film 43 (only the first region 71 is illustrated). Then, the photoresist film 78 that is on the first silicon oxide film 41 is removed by ashing the photoresist film 78. Then, the semiconductor substrate 1 is cleaned. Other than particles, for example, the native oxide film that is formed on the surface of the semiconductor substrate 1 when performing the ashing, etc., also are removed when cleaning the semiconductor substrate 1. Thereby, the surface of the semiconductor substrate 1, e.g., silicon, is exposed at the first and second regions 71 and 72.

Then, as shown in FIG. 5D, the first silicon nitride film 51 is formed using, for example, CVD on the first to third silicon oxide films 41 to 43 and on the first and second regions 71 and 72 (only the first region 71 is illustrated).

Thus, for example, the semiconductor device 100 according to the embodiment can be manufactured by adding processes such as:

a. Form photoresist film 78.

b. Expose and develop the photoresist film 78.

c. Etch the first silicon oxide film 41.

d. Remove the photoresist film 78.

e. Clean the semiconductor substrate 1.

### First Variation

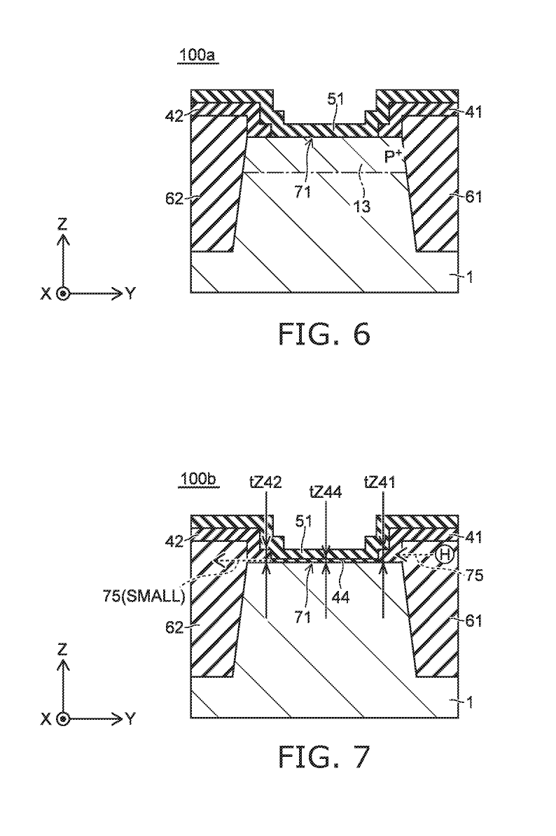

FIG. 6 is a schematic cross-sectional view illustrating a semiconductor device 100a according to a first variation of the embodiment.

As shown in FIG. 6, for example, a third semiconductor region (P⁺) 13 that has a higher p-type impurity concentration than the P-type semiconductor substrate 1 may be provided at each of the first and second regions 71 and 72 (only the first region 71 is illustrated). For example, the p-type impurity concentration of the third semiconductor region 13 is not less than the concentration that can provide ohmic contacts to the first and second conductors CS1 and CS2.

It is favorable not to have P-N junctions at the first and second regions 71 and 72. For each of the semiconductor devices 100 and 100a, there are no P-N junctions at the first and second regions 71 and 72. The region where a P-N junction is provided is, for example, an active area AA of the transistor 3.

For example, in the case where the first silicon nitride film 51 directly contacts the semiconductor substrate 1 including silicon, there is a possibility that crystal defects may be induced by the stress. As described above, for example, the crystal defects worsen easily in the characteristic improvement anneal using deuterium. If the crystal defects undesirably straddle the P-N junction, the junction leakage current increases.

Also, in the case where the first silicon nitride film 51 directly contacts the active area AA, there is a possibility that the first silicon nitride film 51 may provide trap sites of the charge.

From such a perspective, for example, it is favorable for the first and second regions 71 and 72 to be provided not in the active area AA but in a passive area such as the semiconductor substrate 1 or a well region.

It is favorable for the conductivity type of the first and second regions 71 and 72 to be the P-type. For example, the P-type semiconductor substrate 1 and the P-type well region are biased to ground potential (0 V). Even in the case where the first silicon nitride film 51 directly contacts the P-type semiconductor substrate 1 and the P-type well region biased to the ground potential, the first silicon nitride film 51 does not easily provide trap sites of the charge.

It is particularly favorable for the first and second regions 71 and 72 to be set in the tap regions 1sta and 1stb provided in the semiconductor substrate 1 and the tap regions (not illustrated) provided in the well region. Originally, the tap regions are regions existing in the semiconductor chip. Even in the case where the first and second regions 71 and 72 are newly provided in the semiconductor chip, the increase of the surface area of the semiconductor chip can be suppressed.

### Second Variation

FIG. 7 is a schematic cross-sectional view illustrating a semiconductor device 100b according to a second variation of the embodiment.

As shown in FIG. 7, a film 44 that includes silicon oxide may be provided on each of the first and second regions 71 and 72 (only the first region 71 is illustrated). However, a thickness tZ44 in the Z-axis direction of the film 44 is thinner than each of thicknesses tZ41 to tZ43 in the Z-axis direction of the first to third silicon oxide films 41 to 43 (only the thicknesses tZ41 and tZ42 are illustrated). One example of the film 44 is a native oxide film.

Originally, it is favorable for the first silicon nitride film 51 to directly contact the semiconductor substrate 1 at the first and second regions 71 and 72. However, even in the case where the film 44 is provided between the semiconductor substrate 1 and the first silicon nitride film 51, the penetration path 75 of hydrogen is small if the thickness tZ44 is set to be thinner than each of the thicknesses tZ41 to tZ43. Accordingly, in the semiconductor device 100b according to the second variation as well, compared to the semiconductor device 100r according to the reference example (FIG. 4A), the circumstances (1) to (4), etc., recited above can be improved. As described above, for example, the thicknesses tZ41 to tZ43 are set to be 10 nm or more to suppress the action of the first silicon nitride film 51 as trap sites. Therefore, for example, it is sufficient to set the thickness tZ44 to be less than 10 nm.

### Third Variation

The semiconductor device 100 according to the embodiment includes the two first and second regions 71 and 72. However, it is also possible for the semiconductor device 100 to include only the first region 71. This is because there is a tendency for the circumstances (1) to (4), etc., recited above to be pronounced at locations in the peripheral circuit region 1p proximal to the stacked body 2. Accordingly, the first region 71 may be provided between the transistor 3 and the stacked body 2; and the stacked structure of the semiconductor substrate 1 and the first silicon nitride film 51 may be provided at the first region 71.

However, in the case where the semiconductor device 100 includes the two first and second regions 71 and 72, an advantage is obtained in that both the penetration of the hydrogen from the cell region 1c and the penetration of the hydrogen from the scribe line 1sl can be suppressed.

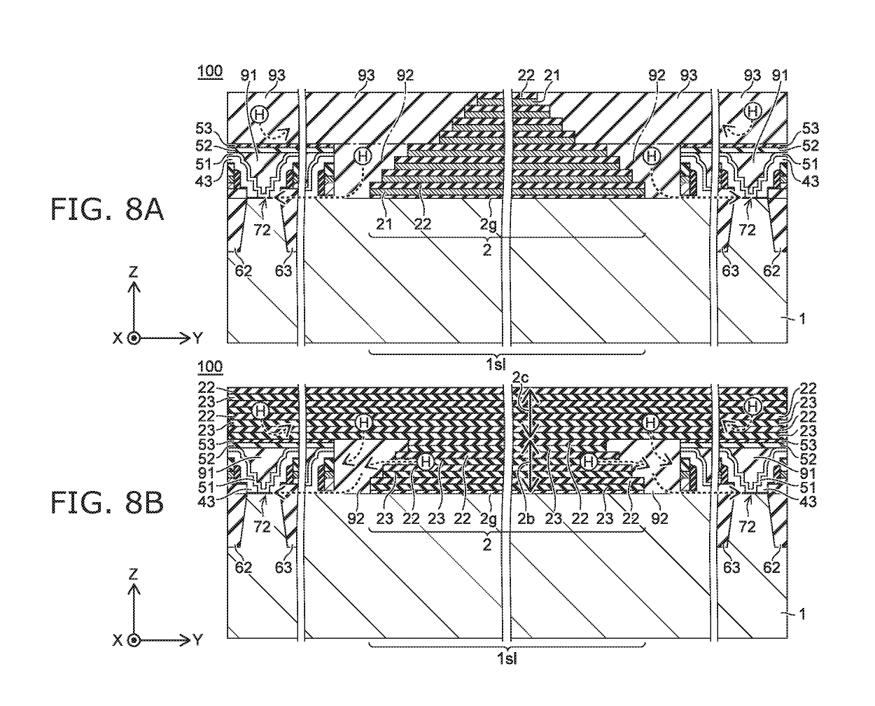

FIG. 8A is a schematic cross-sectional view illustrating a state before dicing the semiconductor device 100 according to the embodiment.

For example, as shown in FIG. 8A, there are cases where the stacked body 2 is provided also inside the scribe line 1sl.

For example, this is to provide a TEG (Test Element Group) according to the memory cells. In the case where the stacked body 2 is provided inside the scribe line 1sl, there is a possibility that hydrogen may penetrate into the peripheral circuit region 1p from the scribe line 1sl.

Such a possibility can be reduced by providing the stacked structure of the semiconductor substrate 1 and the first silicon nitride film 51 at the second region 72. The second region 72 is positioned between the second silicon oxide film 42 and the third silicon oxide film 43 and surrounds the second silicon oxide film 42 in the X- and Y-axis directions.

Accordingly, according to the semiconductor device 100 according to the embodiment, the penetration of the hydrogen into the peripheral circuit region 1p can be suppressed from both the stacked body 2 provided inside the cell region 1c and the stacked body 2 provided inside the scribe line 1sl.

FIG. 8B is a schematic cross-sectional view illustrating a state during the manufacturing of the semiconductor device 100 according to the embodiment. The formation process of the stacked body 2 is shown in FIG. 8B.

When forming the stacked body 2 as shown in FIG. 8B, a portion (a portion distal to the semiconductor substrate 1) 2c that is higher than about the second silicon nitride film 52 and a portion (a portion proximal to the semiconductor substrate 1) 2b that is at and lower than the second silicon nitride film 52 may be made separately. In such a case, the insulating layers 22 and sacrificial films 23 of the portion 2c are formed on the entire wafer on the second silicon nitride film 52. The sacrificial films 23 include, for example, silicon nitride. Therefore, there is a possibility that the hydrogen included in the nitriding agent may penetrate into the peripheral circuit region 1p from both the cell region 1c and the scribe line 1sl. In FIG. 8B, only the stacked body 2 that is provided in the scribe line 1sl is shown.

Such a possibility also can be reduced by providing the stacked structure of the semiconductor substrate 1 and the first silicon nitride film 51 at both the first and second regions 71 and 72.

### Example of Memory Cell

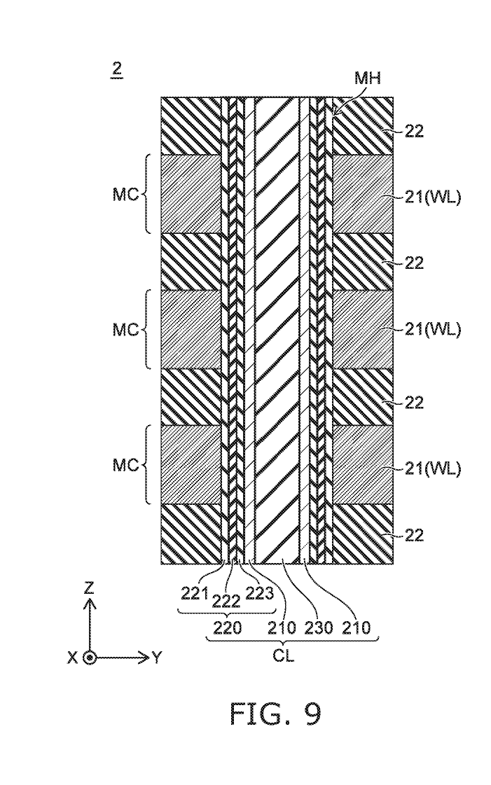

The semiconductor device according to the embodiment is nonvolatile memory including memory cells having a three-dimensional structure. FIG. 9 is a schematic cross-sectional view illustrating memory cells having a three-dimensional structure. One simplified example of the memory cells having the three-dimensional structure is shown in FIG. 9.

As shown in FIG. 9, the stacked body 2 includes the multiple conductive layers 21 and the multiple insulating layers 22. The conductive layers 21 and the insulating layers 22 are stacked alternately in the Z-axis direction. The conductive layers 21 are included in word lines (WL), a source-side selection gate line, and a drain-side selection gate line and are electrically connected to, for example, a row decoder (ROWDEC: FIG. 1A). Only word lines are shown in FIG. 9. The conductive layers 21 include, for example, tungsten as a conductive body. The insulating layers 22 include, for example, silicon oxide and electrically insulate the conductive layers 21 from each other.

A memory hole MH is provided inside the stacked body 2. The memory hole MH extends in the Z-axis direction. Although not particularly illustrated, the configuration of the memory hole MH in the XY plane is a circle or an ellipse. The columnar portion CL is provided inside the memory hole MH. The columnar portion CL includes a semiconductor body 210, a memory film 220, and a core layer 230.

The semiconductor body 210 is provided inside the memory hole MH. The configuration of the semiconductor body 210 is, for example, a tubular configuration including a bottom. The semiconductor body 210 includes, for example, silicon. The silicon is, for example, polysilicon made of amorphous silicon that is crystallized. The conductivity type of the silicon is, for example, the P-type. The semiconductor body 210 is electrically connected between the first semiconductor region 11 and a bit line (not illustrated). For example, the bit line is electrically connected to a sense amplifier (SA: FIG. 1A).

The memory film 220 is provided between the semiconductor body 210 and the inner wall of the memory hole MH. The configuration of the memory film 220 is, for example, a tubular configuration. Multiple memory cells MC are stacked in the Z-axis direction and are disposed between the semiconductor body 210 and each of the conductive layers 21 used as the word lines. The memory film 220 includes a cover insulating film 221, a charge-storable film 222, and a tunneling insulating film 223.

The cover insulating film 221 is provided between the charge-storable film 222 and the conductive layers 21 and between the charge-storable film 222 and the insulating layers 22. The cover insulating film 221 includes, for example, silicon oxide. The cover insulating film 221 protects the charge-storable film 222 so that the charge-storable film 222 is not etched when replacing the sacrificial films (not illustrated) with the conductive layers 21.

The charge-storable film 222 is provided between the cover insulating film 221 and the tunneling insulating film 223. The charge-storable film 222 includes, for example, silicon nitride and has trap sites that trap charge inside a film. The portion of the charge-storable film 222 interposed between the semiconductor body 210 and the conductive layers 21 used as the word lines functions as a charge storage portion. The threshold voltage of the memory cell MC changes due to the existence or absence of the charge inside the charge storage portion or due to the amount of the charge trapped inside the charge storage portion. Thereby, the memory cell MC stores information.

The tunneling insulating film 223 is provided between the semiconductor body 210 and the charge-storable film 222. The tunneling insulating film 223 includes, for example, silicon oxide, or silicon oxide and silicon nitride. The tunneling insulating film 223 is a potential barrier between the semiconductor body 210 and the charge-storable film 222. Tunneling of electrons or holes occurs in the tunneling insulating film 223 when the electrons are injected from the semiconductor body 210 into the charge storage portion (a program operation) and when the holes are injected from the semiconductor body 210 into the charge storage portion (an erase operation).

The core layer 230 fills the interior of the semiconductor body 210 having the tubular configuration. The configuration of the core layer 230 is, for example, a columnar configuration. The core layer 230 includes, for example, silicon oxide and is insulative.

For example, the semiconductor device 100 according to the embodiment multiply includes the memory cells MC such as those shown in FIG. 9 inside the columnar portion CL.

Thus, according to the embodiments, a semiconductor device can be provided in which it is possible to suppress the fluctuation of the element characteristics of the semiconductor element.

The embodiments of the invention are described while referring to specific examples and several variations. However, the embodiments of the invention are not limited to these specific examples and variations. Also, the embodiments recited above are not the only embodiments of the invention. For example, the first silicon nitride film 51 is provided on the first region 71, on the first to third silicon oxide films 41 to 43, and on the second region 72. However, it is sufficient for the first silicon nitride film 51 to directly contact, for example, at least the semiconductor substrate 1 in the first region 71, or for the first silicon nitride film 51 to be provided on at least the first region 71 with a film including silicon oxide interposed such that, for example, the thickness in the Z-axis direction of the film is thinner than the first to third silicon oxide films 41 to 43.

One skilled in the art may similarly practice the invention by appropriately selecting specific configurations of components such as the semiconductor substrate, the element separation region, the stacked body, the memory cell, the transistor, etc., from known art; and such practice is within the scope of the invention to the extent that similar effects can be obtained. Any two or more components of the examples may be combined within the extent of technical feasibility and are within the scope of the invention to the extent that the spirit of the invention is included.

All semiconductor devices practicable by an appropriate design modification by one skilled in the art based on the semiconductor devices described above as embodiments of the invention also are within the scope of the invention to the extent that the spirit of the invention is included.

Various modifications and alterations within the spirit of the invention will be readily apparent to those skilled in the art; and such modifications and alterations also should be seen as being within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a semiconductor substrate of a first conductivity type, the semiconductor substrate including a cell region spreading in a second direction and in a third direction, the second direction crossing a first direction, the third direction crossing the first direction and the second direction;
a stacked body provided in the cell region and included in a memory cell array, the stacked body including a conductive layer and an insulating layer stacked alternately along the first direction;
a transistor disposed on the semiconductor substrate between the stacked body and an edge portion of the semiconductor substrate, the transistor being included in a peripheral circuit of the memory cell array;
a first silicon oxide film surrounding the stacked body in the second and third directions on the semiconductor substrate and being disposed between the stacked body and the transistor;
a second silicon oxide film surrounding the first silicon oxide film and being separated from the first silicon oxide film in the second and third directions on the semiconductor substrate, the second silicon oxide film being disposed between the edge portion and the first silicon oxide film; and
a first silicon nitride film including a portion provided on the substrate in a first region, the first region being positioned between the stacked body and the transistor and between the first silicon oxide film and the second silicon oxide film, the portion surrounding the stacked body in the second and third directions on the semiconductor substrate.

2. The device according to claim 1, wherein the first silicon nitride film is provided on the first region, the first silicon oxide film, and the second silicon oxide film.

3. The device according to claim 1, further comprising a third silicon oxide film surrounding the second silicon oxide film and being separated from the second silicon oxide film in the second and third directions on the semiconductor substrate, the third silicon oxide film being disposed between the edge portion and the second silicon oxide film,
the first silicon nitride film further including a portion provided on the substrate in a second region, the second region being positioned between the second silicon oxide film and the third silicon oxide film, the portion surrounding the transistor in the second and third directions on the semiconductor substrate.

4. The device according to claim 3, wherein the first silicon nitride film is provided on the first region, the second region, the first silicon oxide film, the second silicon oxide film, and the third silicon oxide film.

5. The semiconductor device according to claim 3, further comprising:
a first element separation region including silicon oxide, being disposed between the edge portion and the stacked body, and surrounding the stacked body in the second and third directions; and
a second element separation region including silicon oxide, being disposed between the edge portion and the first element separation region, surrounding the first element separation region in the second and third directions, and being separated from the first element separation region in the second and third directions,
the first region being positioned between the first element separation region and the second element separation region.

6. The device according to claim 5, further comprising a third element separation region including silicon oxide, being disposed between the edge portion and the second element separation region, surrounding the second element separation region in the second and third directions, and being separated from the second element separation region in the second and third directions,
the second region being positioned between the second element separation region and the third element separation region.

7. The device according to claim 1, further comprising a second silicon nitride film,
the transistor including a first gate structure body, and
the second silicon nitride film covering the first gate structure body.

8. The device according to claim 7, further comprising a second gate structure body disposed between the first gate structure body and the stacked body,
the second silicon nitride film covering the first gate structure body and the second gate structure body to be continuous from the first gate structure body to the second gate structure body.

9. The device according to claim 8, wherein the first silicon nitride film covers a side surface of the second gate structure body on the first gate structure body side.

10. The device according to claim 8, further comprising a third gate structure body disposed between the first gate structure body and the edge portion,
the second silicon nitride film further covering the third gate structure body to be continuous from the first gate structure body to the third gate structure body.

11. The device according to claim 10, wherein the first silicon nitride film covers a side surface of the second gate structure body on the first gate structure body side and a side surface of the third gate structure body on the first gate structure body side.

12. The device according to claim 1, further comprising a first conductor piercing the first silicon nitride film and being electrically connected to the substrate in the first region.

13. The device according to claim 12, wherein the substrate in the first region is of the first conductivity type.

14. The device according to claim 3, further comprising a second conductor piercing the first silicon nitride film and being electrically connected to the substrate in the second region.

15. The device according to claim 14, wherein the substrate in the second region is of the first conductivity type.

16. The device according to claim 1, wherein the first silicon nitride film directly contacts the semiconductor substrate in the first region.

17. The device according to claim 3, wherein the first silicon nitride film directly contacts the semiconductor substrate in the second region.

18. The device according to claim 1, further comprising a film including silicon oxide and being provided between the semiconductor substrate and the first silicon nitride film in the first region,
a thickness in the first direction of the film being thinner than a thickness in the first direction of the first silicon oxide film and thinner than a thickness in the first direction of the second silicon oxide film.

19. The device according to claim 3, further comprising a film including silicon oxide and being provided between the semiconductor substrate and the first silicon nitride film in the second region,
a thickness in the first direction of the film being thinner than a thickness in the first direction of the second silicon oxide film and thinner than a thickness in the first direction of the third silicon oxide film.

20. The device according to claim 1, wherein the stacked body further includes a plurality of memory cells provided along the first direction.
